(19) United States
(12) Patent Application Publication
(10) Pub. No.: US 2010/0243026 A1
(43) Pub. Date: Sep. 30, 2010

(54) SOLAR CELL MODULE AND SOLAR CELL

(75) Inventor: Masaki Shima, Uji City (JP)

Correspondence Address: MOTS LAW, PLLC, 1629 K STREET N.W., SUITE 602, WASHINGTON, DC, 20006-1635, US

(73) Assignee: Sanyo Electronic Co., Ltd, Osaka (JP)

(21) Appl. No.: 12/730,507

(22) Filed: Mar. 24, 2010

(30) Foreign Application Priority Data
Mar. 27, 2009 (JP) 2009-079053

(51) Int. Cl. H01L 31/042; H01L 31/00

(52) U.S. Cl. 136/244; 136/256

(57) ABSTRACT

A solar cell module includes: a translucent front surface member; a rear surface member; solar cells disposed between the front surface member and the rear surface member and electrically connected to each other; and a translucent sealing resin filled between the front surface member and the rear surface member and fixing the solar cells to the front surface member and the rear surface member. The solar cell includes: a photoelectric conversion body having a semiconductor junction to form an electric field isolating carriers; a suppression layer provided between the front surface member and the photoelectric conversion body and configured to suppress recombination of minority carriers; and an inclined surface provided at the outer edge of the suppression layer and extending in a direction non-parallel to the normal line of the solar cell.

### CROSS REFERENCE TO RELATED APPLICATIONS

This application of the invention titled “Solar Cell Module” is based upon and claims the benefit of priority under 35 USC 119 from prior Japanese Patent Application No. 2009-079053, filed on Mar. 27, 2009, the entire contents of which are incorporated herein by reference.

### BACKGROUND OF THE INVENTION

1. Field of the Invention

The invention relates to a solar cell module including a plurality of solar cells.

2. Description of the Related Art

Solar cells are expected as a new energy source because they can directly convert clean and inexhaustible sunlight into electricity.

Output per solar cell is as small as several watts. For this reason, when such a solar cell is used as a power supply for a house, a building or the like, normally, a plurality of solar cells are used as a solar cell module in which the plurality of solar cells are electrically connected in series or parallel so as to increase the output of the solar cells to several hundred watts.

The aforementioned solar cell module is configured of the plurality of solar cells which are electrically connected to each other via a conductive member such as copper foil and sealed between a translucent front surface member, such as glass or translucent plastic and a rear surface member made of a weather-resistant film, by a translucent sealant, such as EVA (ethylene vinylacetate), excellent in weather and humidity resistance. Each of the solar cells includes a photoelectric conversion body, a front surface electrode bonded to the front surface of the photoelectric conversion body, and a rear surface electrode provided at the rear surface of the photoelectric conversion body. The photoelectric conversion body is formed by stacking a suppression layer and the like on a photodiode having a semiconductor junction such as a PN junction or a PIN junction.

In a solar cell module disclosed in Japanese Patent Application Publication No. 2001-237448, a semiconductor junction of a photodiode faces to the rear surface member (to the side opposite to the front surface member).

A suppression layer to suppress recombination of minority carriers is formed between the front surface member and the photodiode. Thus light passes through the suppression layer first and then enters the photodiode in the solar cell. Some light is absorbed by the suppression layer, resulting in less light to be entered in the photodiode. It is desired to cause the light incident from the front surface of the photoelectric conversion body to efficiently enter the semiconductor junction of the photodiode.

### SUMMARY OF THE INVENTION

An aspect of the invention is a solar cell including: a translucent front surface member; a rear surface member; solar cells disposed between the front surface member and the rear surface member and electrically connected to each other; and a translucent sealing resin filled between the front surface member and the rear surface member and fixing the solar cells to the front surface member and the rear surface member. Each of the solar cells includes: a photoelectric conversion body having a semiconductor junction to form an electric field isolating carriers; a suppression layer provided between the front surface member and the photoelectric conversion body and configured to suppress recombination of minority carriers; and an inclined surface provided at the outer edge of the suppression layer and extending non-parallel with a direction normal to the solar cell.

According to an aspect of the invention, it is possible to cause light incident on the front surface of the solar cell to enter the photoelectric conversion body through the inclined surface provided at the outer edge of the solar cell, without passing through the suppression layer.

### BRIEF DESCRIPTION OF THE DRAWINGS

FIG. 1 is a plan view schematically showing a solar cell module of an embodiment of the invention.

FIG. 2 is a cross-sectional view schematically showing the solar cell module.

FIG. 3 is a schematic cross-sectional view showing a solar cell of the solar cell module.

FIG. 4 is a schematic cross-sectional view showing a modification of the solar cell.

FIG. 5 is a schematic cross-sectional view showing a portion of the solar cell module.

FIG. 6 is a plan view showing a portion of the solar cell module.

### DETAILED DESCRIPTION OF EMBODIMENTS

Embodiments of the invention are described in detail with reference to the drawings. Note that, the same reference numerals are used to denote the same or equivalent portions in the drawings, and the description of the portions are not repeated in order to avoid redundant description.

Prepositions, such as “on”, “over” and “above” may be defined with respect to a surface, for example a layer surface, regardless of that surface's orientation in space. The preposition “above” may be used in the specification and claims even if a layer is in contact with another layer. The preposition “on” may be used in the specification and claims when a layer is not in contact with another layer, for example, when there is an intervening layer between them.

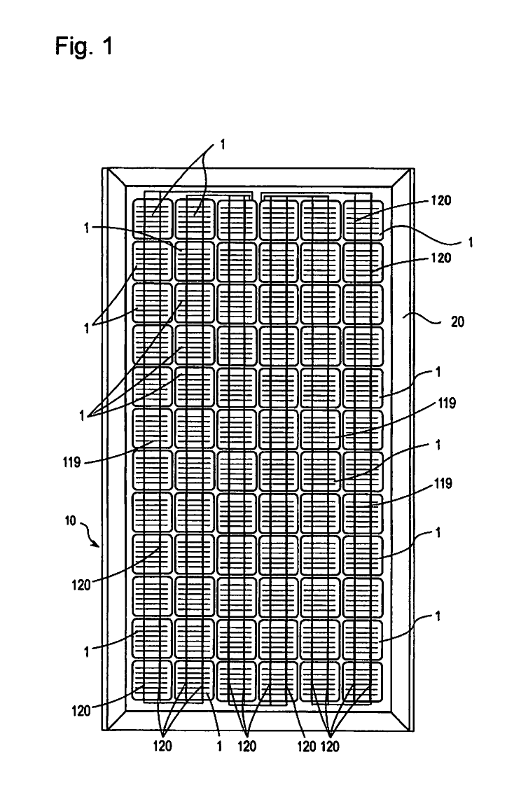

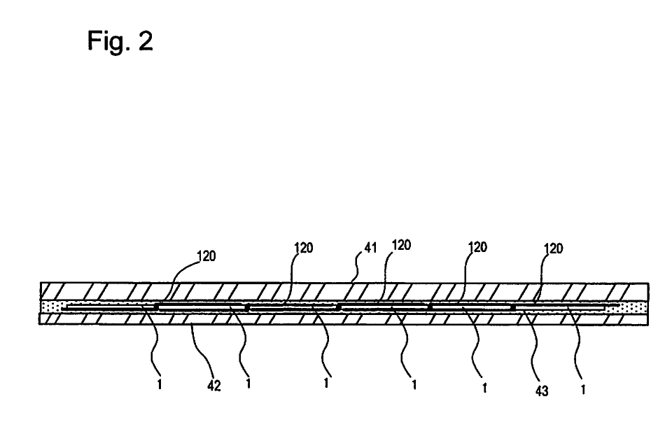

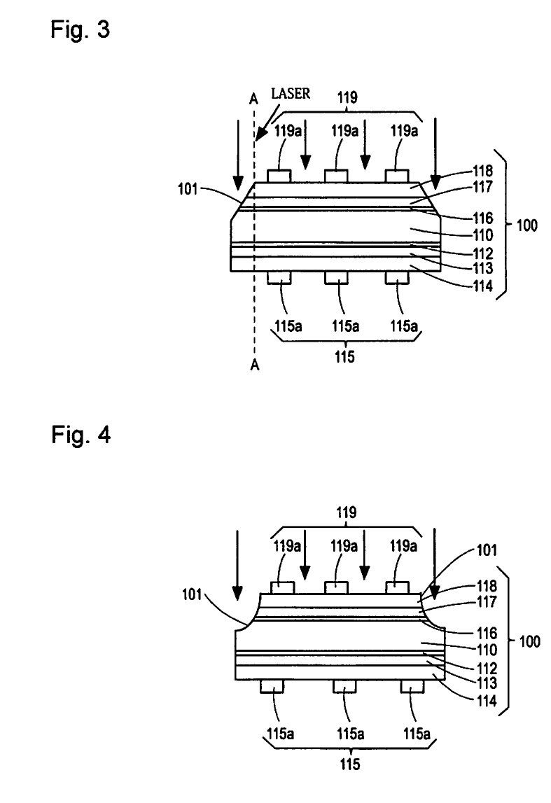

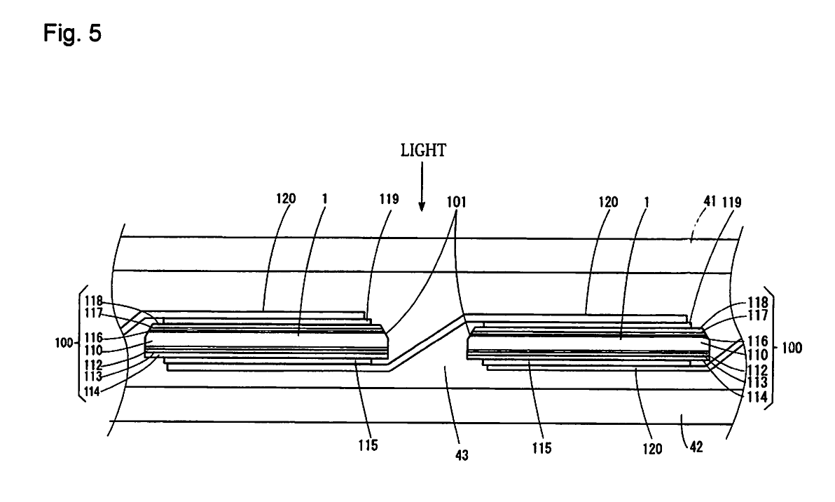

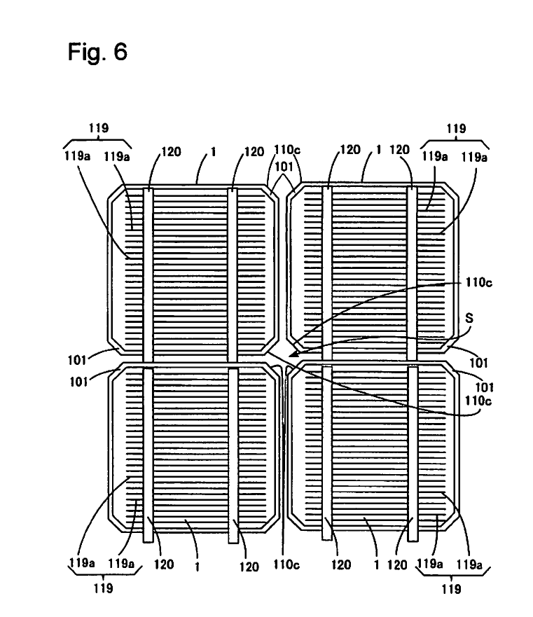

FIG. 1 is a plan view schematically showing a solar cell module of an embodiment of the invention. FIG. 2 is a cross-sectional view schematically showing the solar cell module. FIG. 3 is a schematic cross-sectional view showing a solar cell of the solar cell module. FIG. 4 is a schematic cross-sectional view showing a modification of the solar cell. FIG. 5 is a schematic cross-sectional view showing a portion of the solar cell module. FIG. 6 is a plan view showing the portion of the solar cell module.

First, solar cell module 10 is described with reference to drawings.

As shown in FIGS. 1 and 2, solar cell module 10 includes plate-shaped solar cells 1. Solar cells 1 are arranged in a matrix in a plane. Each solar cell 1 is formed of a crystalline semiconductor comprised of single crystalline silicon, polycrystalline silicon, or the like, having a thickness of approximately 0.15 mm. In addition, each solar cell 1 is substantially formed in a square with a side length of 104 mm or a square with a side length of 125 mm. Solar cell 1 is, however, not limited to this, and a different solar cell may be used.

In solar cell 1, a n-type region and a p-type region are formed, for example, and a semiconductor junction generating an electric field to isolate carriers at the interface between the n-type region and the p-type region is thereby formed. The n-type region and the p-type region can be formed from one of the following semiconductors used for a solar cell, or a combination of the semiconductors. The semiconductors used for the solar cells may include: a crystalline semiconductor such as single crystalline silicon or polycrystalline silicon; a compound semiconductor such as GaAs or InP; and a thin film semiconductor having an amorphous state or a microcrystalline state such as thin film Si or CuInSe. For example, a solar cell is used in which the properties of the heterojunction interface are improved by inserting an intrinsic amorphous silicon layer between a single crystalline silicon layer and an amorphous silicon layer having conductivities opposite to each other, and thus reducing defects at the interface.

As shown in FIGS. 5 and 6, each solar cell 1 is electrically connected to another solar cell 1 adjacent thereto by wiring member 120 comprised of a flat copper foil or the like. Specifically, one end of wring member 120 is connected to collective electrode 119 exposed on the front surface of one solar cell 1, and the other end of wiring member 120 is connected to collective electrode 115 exposed on the rear surface of another solar cell 1 which is adjacent to the one solar cell 1 mentioned earlier. These solar cells 1 are thereby connected in series by wiring member 120 to form solar cell module 10 generating a predetermined output, e.g., an output of 200 watts, via a transition wire or an extraction line.

As shown in FIG. 2, a plurality of solar cells 1 electrically connected to each other via wiring members 120 are sealed between translucent front surface member 41 such as glass or translucent plastic, and rear surface member 42 made of a weather-resistant film, a glass or plastic member by translucent sealing member 43 such as EVA, which has excellent weather resistance and humidity resistance.

Solar cell module 10 is fit into outer frame 20 made of aluminum or the like, by use of a sealing member on the outer edge of solar cell module 10 as appropriate. Outer frame 20 is made of aluminum, stainless steel or steel plate roll forming member or the like. A terminal box (not shown) is provided on the rear side of rear surface member 42 as appropriate, for example.

The structure of solar cell 1 is described with reference to FIG. 3. Note that, in order to facilitate understanding of the structure of each layer, thin layers are not described in accordance with the actual film thickness but are displayed in an enlarged manner in FIG. 3.

Solar cell 1 includes plate-shaped photoelectric conversion body 100, first collector electrode 115 formed on the surface of photoelectric conversion body 100, and second collector electrode 119 formed on the opposite surface of photoelectric conversion body 100. Photoelectric conversion body 100 generates photogenerated carriers by absorption of incident light. The photogenerated carriers refer to electrons and holes generated in photoelectric conversion body 100 by incident light. Photoelectric conversion body 100 is comprised of a plate-shaped crystalline semiconductor, for example. As shown in FIG. 3, photoelectric conversion body 100 of solar cell 1 includes, a crystalline semiconductor substrate, n-type single crystalline silicon substrate 110 having a thickness of approximately 200 μm. Single crystalline silicon substrate 110 is fabricated by the steps of: cutting out a cylindrical single crystalline silicon block with an appropriate dimension (normally, 40 to 50 cm length) from a cylindrical silicon ingot (normally, at least 1 m length) obtained by a pulling method; processing the cylindrical single crystalline silicon block into a rectangular column; and slicing the rectangular column-shaped single crystalline silicon block. Note that, single crystalline silicon substrate 110 of the embodiment is processed into a shape obtained by cutting and removing four corner portions of the square-shaped silicon block.

Although not illustrated, pyramid shaped asperities each having a height from several μm to several tens of μm are formed on the surface of n-type single crystalline silicon substrate 110 to confine light. Intrinsic i-type amorphous silicon layer 112 is formed on n-type single crystalline silicon substrate 110. In addition, p-type amorphous silicon layer 113 is formed on i-type amorphous silicon layer 112. N-type single crystalline silicon substrate 110, i-type amorphous silicon layer 112 and p-type amorphous silicon layer 113 form a photodiode. A semiconductor junction forming an electric field to isolate carriers is formed in the photodiode by the pn junction of n-type single crystalline silicon substrate 110 and p-type amorphous silicon layer 113.

Transparent conductive film 114 is formed on p-type amorphous silicon layer 113 by a sputtering method.

Collector electrode 115 is made of silver and formed in a predetermined region of the front surface of transparent conductive film 114. Collector electrode 115 is an electrode to collect the photogenerated carriers generated by photoelectric conversion body 100. Collector electrode 115 includes a plurality of fine electrodes 115a formed parallel to each other, for example. The width, pitch and thickness of each fine electrode 115a are approximately 100 μm, 2 mm and 60 μm, respectively. Approximately 50 fine electrodes 115a are formed on the front surface of photoelectric conversion body 100. Such fine electrodes 115a are formed by screen-printing silver paste, for example, and then curing the silver paste at a temperature of a hundred and several tens of degrees.

In addition, n-type amorphous silicon layer 117 serving as a suppression layer to suppress recombination of minority carriers is formed on the other surface of n-type single crystalline silicon substrate 110 with i-type amorphous silicon layer 116 interposed there-between. The formation of n-type amorphous silicon layer 117 on the different surface of n-type single crystalline silicon substrate 110 in this manner can reduce the carrier loss due to recombination.

Transparent conductive film 118 is provided on n-type amorphous silicon layer 117, and collective electrode 119 made of silver paste is formed in a predetermined region on transparent conductive film 118. Collector electrode 119 includes a plurality of fine electrodes 119a formed parallel to each other as in the case of collective electrodes 115 described above.

Note that, although n-type amorphous silicon layer 117 is used as a suppression layer to suppress the recombination of carriers in this embodiment, the suppression layer is not limited to this. A nitride silicon film (SiN), an oxide silicon film (SiO), amorphous silicon carbide (a-SiC), amorphous silicon oxide (a-SiO), microcrystalline silicon (μc-Si), or the like can be used as the suppression layer as well.

In the example shown in FIG. 3, photoelectric conversion body 100 corresponds to the area from transparent conductive film 114 of the one surface to transparent conductive film 118 of the opposite surface.

In the solar cell shown in FIG. 3, collector electrode 115 formed on the front surface includes fine electrodes 115a, and collector electrode 119 formed on the rear surface includes fine electrodes 119a. This allows the solar cell to be a dual surface solar cell capable of generating electricity by light incident on both the front and rear surfaces.

The side of solar cell 1 having n-type amorphous silicon layer 117 serving as the suppression layer is disposed toward front surface member 41. Specifically, n-type amorphous silicon layer 117 serving as the suppression layer is disposed on the light incident side, and thus, light passes through n-type amorphous silicon layer 117 and i-type amorphous silicon layer 116, and then enters single crystalline silicon substrate 110.

Here, as shown in FIG. 3, inclined surface 101 is formed at the edge of n-type amorphous silicon layer 117 and non-parallel with the normal direction of solar cell 1, that is, not parallel with n-type single crystalline silicon substrate 110 as formed. Inclined surface 101 may be provided only at each corner portion 110c between sides of the outer edge of the front surface of photoelectric conversion body 100. In this embodiment, however, inclined surface 101 is formed at the entire outer edge (all of the four sides) of the front surface of photoelectric conversion body 100, that is, inclined surface 101 is formed at the entire outer edge of n-type amorphous silicon layer 117.

Moreover, inclined surface 101 is formed to have a depth to reach n-type single crystalline silicon substrate 110 as shown in FIG. 3. Inclined surface 101 is formed by irradiating n-type amorphous silicon layer 117, i-type amorphous silicon layer 116 and n-type single crystalline silicon substrate 110 with a laser in a direction from a center side of substrate 110 toward the outer edge thereof at a desired angle with respect to normal line A-A of substrate 110, for example.

As shown in FIGS. 5 and 6, in solar cell module 10, wiring members 120 are respectively pressure bonded to collector electrode 119 on the side of he front surface (light receiving surface) and collector electrode 115 on the side of the rear surface through an adhesion layer. Accordingly, part of collector electrode 119 is coated with wiring member 120, and the other part of collector electrode 119 is exposed from wiring member 120 and faces front surface member 41. Likewise, part of collector electrode 115 is coated with wiring member 120, and the other part of collector electrode 115 is exposed from wiring member 120 and faces rear surface member 42.

The adhesion layer may be made of a resin adhesive agent containing an epoxy resin as a major component and a cross-linking accelerator as a compounding agent. The cross-linking accelerator rapidly accelerates cross-linkage by a heating process at a temperature of 180° C. to cure the adhesion layer in approximately 15 seconds. The thickness of the adhesive layer is approximately 0.01 to 0.05 mm and is preferably equal to the thickness of wiring member 120 or even thinner than the width of the wiring member in consideration of blocking of incident light. In this embodiment, a resin adhesive agent formed in a belt-like film sheet having a width of 1.5 mm and a thickness of 0.02 mm can be used.

Moreover, as the resin adhesive agent, one that includes no conductive particles or one that includes conductive particles can be used. In a case where a resin adhesive agent including no conductive particles is used, a part of the surface of collector electrode 119 (115) is brought into direct contact with the surface of wiring member 120 for electrical connection. In this case, it is preferable to form, as wiring member 120, a conductive film softer than collective electrode 119 (115), such as tin (Sn) or solder, on a surface of a conductor made of a copper foil plate or the like, and thereby to make the electrical connection in a state where part of collective electrode 119 (115) is pressed into the conductive film.

On the other hand, in a case where a resin adhesive agent containing conductive particles is used, the conductive particles are brought into contact with both of the surfaces of collector electrode 119 (115) and wiring member 120 to electrically connected to collector electrode 119 (115) and wiring member 120. In this case, more preferable electrical connection can be made when a part of the surface of collective electrode 119 (115) is brought into direct contact with the surface of wiring member 120.

Although collector electrode 115 (119) and wiring member 120 are connected to each other by use of a resin adhesive agent in the aforementioned example, solder may be used instead of the resin adhesive agent. In this case, collector electrode 119 (115) has a connection electrode made of a solderable metal and electrically connecting a plurality of fine electrodes 119a (115a) with each other. Thereby, wiring member 120 can be bonded to the surface of the connection electrode by use of solder.

As described above, the formation of inclined surface 101 causes the surface of substrate 110 to be exposed at the outer edge of solar cell 1 as shown in FIG. 3. This prevents light from being absorbed by amorphous silicon layers 117 and 116 on the light incident side when light enters in a direction indicated by arrows in FIG. 3, and allows the light to directly enter the photodiode formed of n-type single crystalline silicon substrate 110, i-type amorphous silicon layer 112 and p-type amorphous silicon layer 113. As a result, the light absorption loss is suppressed, and the output characteristics can be thus improved.

FIG. 4 is a schematic cross-sectional view showing a modification of the solar cell. FIG. 4 shows inclined surfaces 101 in a mesa shape formed by irradiating the edge portion of substrate 110 with a laser in the normal direction, then laser scribing of substrate 110 to the side of the center of substrate 110, and breaking the substrate thereafter. In solar cell 1 formed by this method, substrate 110 is exposed on the outer edge of the solar cell, thus allowing light to directly enter substrate 110 while the light is not absorbed by amorphous silicon 117 and 116 on the light incident side when the light enters in a direction shown by arrows in FIG. 4.

As shown in FIG. 6, the outer edge of each solar cell 1 is formed having four sides when viewed in the normal direction of solar cell 1. Each of four corner portions 110c (each being a position where adjacent two sides intersect with each other) of the outer edge of solar cell 1 is cut and thus inclined with respect to both of the two sides. For this reason, when solar cell module 10 is formed, cut corner portions 100c face one another at a position where four solar cells 1 face one another, thereby forming space S, which is substantially a rhomboid shape. The amount of light passing through space S is larger than the amount of light passing through a gap between two sides of respective adjacent two solar cells 1. For this reason, the amount of light reflected by rear surface member 42 and entering the front side again at space S is larger than the amount of light at the other regions. Accordingly, it is possible to improve the output characteristics by actively increasing the amount of light to be absorbed at corner portions 110c in this manner. The provision of inclined portion 101 at each corner portion 110c contributes to the improvement in the output characteristics. Although inclined surface 101 is formed at the entire outer edge of each of the solar cells in the embodiment shown in FIG. 6, it is possible to improve the output characteristics by providing inclined surface 101 only at each corner portion 101c.

Next, solar cell 1 having inclined surfaces 101 of the shape shown in FIG. 4 described above, and a solar cell having the same structure as that of solar cell 1 except that the inclined surface is not provided thereto are prepared. Then, the characteristics of the solar cells are measured. Table 1 shows the result of the measurement. Table 1 shows values while taking as reference values the measured values of the sample not provided with the inclined surfaces.

TABLE 1

| | Voc | Isc | F.F. | Pmax |
|---|---|---|---|---|
| Without Inclined Surface | 1.000 | 1.000 | 1.000 | 1.000 |
| (Conventional Example) | | | | |
| With Inclined Surface | 1.000 | 1.002 | 1.002 | 1.004 |
| (the Invention) | | | | |

It can be understood from the above results that the characteristics of the solar cell is improved according to the embodiment.

Note that, although photoelectric conversion body 100 is formed in the shape obtained by cutting and removing four corner portions 110c of the square, photoelectric conversion body 100 may be formed in a square shape without its corner portions cut and removed.

In addition, collector electrode 115 facing rear surface member 42 may be formed so as to substantially cover the entire surface of photoelectric conversion body 100.

The embodiment disclosed in this description is to be considered as only exemplary and not intended to impose any limitation. It is intended that the scope of the invention is not limited by the embodiment described above, but by the scope of claims appended hereto, and that the scope of the invention include all modifications within the scope of claims and the equivalents to the claims.

What is claimed is:

1. A solar cell module comprising:
a translucent front surface member;
a rear surface member;
solar cells disposed between the front surface member and the rear surface member and electrically connected to each other; and
a translucent sealing resin filled between the front surface member and the rear surface member and fixing the solar cells to the front surface member and the rear surface member, wherein
each of the solar cells comprises:
a photoelectric conversion body having a semiconductor junction to form an electric field isolating carriers;
a suppression layer provided between the front surface member and the photoelectric conversion body and configured to suppress recombination of minority carriers; and
an inclined surface provided at an outer edge of the suppression layer and extending non-parallel with a direction normal to the solar cell.

2. The solar cell module according to claim 1, wherein
the solar cell comprises:
the photoelectric conversion body having a single crystalline semiconductor layer of one conductivity type, an intrinsic amorphous semiconductor layer, and an amorphous semiconductor layer of the other conductivity type stacked in this order; and
a suppression layer provided between the front surface member and the photoelectric conversion body and formed of an amorphous semiconductor layer of the one conductivity type.

3. The solar cell module according to claim 1, wherein
the semiconductor junction is a p-i-n junction in which an amorphous silicon layer of the other conductivity type is provided on a surface of a single crystalline silicon substrate of one conductivity type with an intrinsic amorphous silicon layer interposed therebetween, and
the suppression layer is an amorphous silicon layer of the one conductivity type provided on an opposite surface of the single crystalline silicon substrate of the one conductivity type.

4. The solar cell module according to claim 2, wherein the inclined surface extends from the front surface of the solar cell to the photoelectric conversion body.

5. The solar cell module according to claim 2, wherein the inclined surface extends from the front surface of the solar cell to the single crystalline semiconductor layer of the one conductivity type of the photoelectric conversion body.

6. The solar cell module according to claim 1, wherein the inclined surface is formed at the entire outer edge of the suppression layer.

7. The solar cell module according to claim 1, wherein the inclined surface is linear.

8. The solar cell module according to claim 1, wherein the inclined surface is curved.

9. The solar cell module according to claim 2, wherein
the solar cell further comprises a transparent conductive film provided on a front surface of the suppression layer and thus forming the front surface of the solar cell.

10. The solar cell module according to claim 9, wherein a collector electrode is partially provided on a front surface of the transparent conductive film.

11. The solar cell module according to claim 2, wherein
the solar cell further comprises a transparent conductive film provided on a rear surface of the amorphous semiconductor layer of the other conductivity type and thus forming a rear surface of the solar cell.

12. The solar cell module according to claim 11, wherein a collector electrode is partially provided on a rear surface of the transparent conductive film

13. The solar cell module according to claim 1, wherein
the solar cell is formed in a quadrangle having four sides at the outer edge thereof, and
a corner portion as an intersection of adjacent two of the four sides is formed as a cut portion inclined with respect to both of the adjacent two sides.

14. A solar cell comprising:
a solar cell front surface serving as a light receiving surface;
a solar cell rear surface opposite to the solar cell front surface;
a photoelectric conversion body provided between the solar cell front surface and the solar cell rear surface and having a semiconductor junction to form an electric field isolating carriers; and
a suppression layer provided between the solar cell front surface and the photoelectric conversion body and configured to suppress recombination of minority carriers; and
an inclined surface formed at an outer edge of the solar cell front surface so as to extend at least to the suppression layer from the solar cell front surface, and extending non-parallel with a direction normal to the solar cell front surface.

15. A solar cell comprising:
a solar cell front surface serving as a light receiving surface;
a solar cell rear surface opposite to the solar cell front surface;
a photoelectric conversion body provided between the solar cell front surface and the solar cell rear surface and having a semiconductor junction to form an electric field for isolating carriers; and
a suppression layer provided between the solar cell front surface and the photoelectric conversion body and configured to suppress recombination of minority carriers, and a part of the photoelectric conversion body being out of the suppression layer as seen along a direction normal to the solar cell.
